(19) United States
(12) Patent Application Publication
(10) Pub. No.: US 2023/0049534 A1
(43) Pub. Date: Feb. 16, 2023

(54) SYSTEM FOR ANALYSING PASSIVE NETWORK

(71) Applicants: JAE YONG CHO, Seoul (KR); HUWIN CO., LTD., Seongnam-si (KR)

(72) Inventors: Jae Yong Cho, Seoul (KR); Seungil Jeung, Seongnam-si (KR)

(73) Assignees: JAE YONG CHO, Seoul (KR); HUWIN CO., LTD., Seongnam-si (KR)

(21) Appl. No.: 17/882,598

(22) Filed: Aug. 8, 2022

Related U.S. Application Data
(63) Continuation-in-part of application No. 16/519,226, filed on Jul. 23, 2019.

(30) Foreign Application Priority Data
Apr. 29, 2019 (KR) 10-2019-0049758

(51) Int. Cl. H04L 7/00

(52) U.S. Cl. CPC H04L 7/0054

(57) ABSTRACT

A system for analyzing a passive network is provided, the system being configured to extend the frequency band with the interpolation function of the low frequency band and the extrapolation function of the high frequency band for S-parameters with limited measurement band, adjust the propagation delay time for the band-extended S-parameter to derive the final band-extended S-parameter, and analyze the time response of the passive network on the basis of the output voltage waveform estimated by performing convolution on the impulse response to the derived final band-extended S-parameter and the input voltage waveform of the passive network, thereby improving the time response performance of the passive network without a complex circuit conversion process, and making it possible to be capable of lightweight structures. Furthermore, it is possible to improve the accuracy of the impulse response by adjusting the propagation delay time removed from the band-limited S-parameter.

### CROSS REFERENCE TO RELATED APPLICATION

The present application claims priority to Korean Patent Application 10-2019-0049758, filed Apr. 29, 2019, the entire content of which is incorporated herein for all purposes by this reference.

### BACKGROUND OF THE INVENTION

### Field of the Invention

The present invention relates to a system for analyzing passive network and, more particularly, to a system for analyzing passive network which may evaluate the performance of passive networks by measuring the output of the passive network for the input supplied from the outside with limiting the band to derive the S-parameters and extending the band of the derived band-limited S-parameters.

### Description of the Related Art

A general passive circuit network is provided with a semiconductor package or a printed circuit board, which includes various components and devices, and the output voltage of the passive circuitry with respect to the input voltage is measured by the instrument. Here, the output of the passive network based on the instrument is the S-parameters of the band-limited frequency domain.

To measure the frequency response performance of the passive network, an instrument, such as a vector network analyzer (VNA), is required. The measurement results are obtained as data in the form of S-parameters. Here, the S-parameter includes the frequency response of each input/output terminal of the passive network, and the frequency band thereof is limited according to the measurement bandwidth of the instrument.

The S-parameter may be used to measure the performance for time responses (e.g., output voltage waveforms) of a passive network. Although a method of converting the S-parameters into an equivalent circuit has been used in the related, there are disadvantages that it is complicated and low in accuracy.

Another method is to acquire an output waveform by performing inverse Fourier transform (IFT) on the S-parameters to convert the S-parameters into impulse response and then performing convolution on the impulse response and the input voltage.

However, this method has a problem that the impulse response of the IFT is inaccurate when there is no low-frequency band data of the S-parameter or when the high-frequency band thereof is limited. Such inaccuracy of the impulse response may be confirmed in the form of a causality error in which an error waveform appears in the impulse response of the IFT before the time delay of the passive network, as shown in FIG. 1.

Documents of Related Art

(Patent Document 1) U.S. Patent Application Publication No. 2008/0281893(Optimization of spectrum extrapolation for causal impulse response calculation using the Hilbert transform)

### SUMMARY OF THE INVENTION

Accordingly, the present invention has been made keeping in mind the above problems occurring in the prior art, and an objective of the present invention is to provide a system and method for analyzing the passive network with respect to accurate time response using the band-limited S-parameter of the passive network.

According to an embodiment, there is disclosed a system for analyzing passive network, configured to analyze time response of a passive network with a band-limited S-parameter of an instrument, the system including:

an interpolator removing a propagation delay time from the band limited S-parameter of the instrument, deriving an imaginary part of the S-parameter from which the propagation delay time is removed, adding an interpolation function of a low frequency band and an extrapolation function of a high frequency band to the derived imaginary part to derive an imaginary part of a band-extended S-parameter, and performing IFT after restoring a real part of the band-extended S-parameter by performing Hilbert transform on the imaginary part of the derived band-extended S- parameter to derive an impulse response; and

an analysis device analyzing time response of the passive network by analyzing an output voltage waveform of the passive network estimated by performing convolution on the impulse response and an input voltage waveform of the passive network,

in which the interpolator is configured to adjust the propagation delay time according to a comparison result of a difference between the real part of the band-extended S-parameter and a real part of the band-limited S-parameter with a predetermined reference value.

Preferably, the interpolator may include:

a pre-processing unit that removes the propagation delay time from the band-limited S-parameter and then derives the imaginary part of the band-limited S-parameter from the band-limited S-parameter;

a band extension unit extending the frequency band by adding the interpolation function of the low frequency band and the extrapolation function of the high frequency band to the imaginary part of the derived band-limited S-parameter, restoring the real part of the band-extended S-parameter by performing Hilbert transform on the imaginary part of the band-extended S-parameter, and deriving coefficients of the interpolation function and the extrapolation function by using the difference between the real part of the restored S-parameter and the real part of the S-parameter from which the propagation delay time is removed, to output a final band-extended S-parameter; and

a post-processing unit outputting an impulse response by performing IFT on the derived band-extended S-parameter.

Preferably, the band extension unit may include:

an interpolation function generation module generating the interpolation function of the low frequency band in the imaginary part of the derived band-limited S-parameter;

an extrapolation function generating module generating the extrapolation function of the high frequency band in the imaginary part of the derived band-limited S-parameter;

a frequency extension module extending the measurement band to derive the imaginary part of the band-extended S-parameter by adding the interpolation function of the low frequency band and the extrapolation function of the high frequency band to the imaginary part of the band-limited S-parameter;

a restoration module restoring the real part of the band-extended S-parameter by performing Hilbert transform on the imaginary part of the band-extended S-parameter;

a coefficient derivation module applying an LSE (least square error) technique that minimizes the difference between the real part of the band-extended S-parameter and the real part of the band-limited S-parameter from which the propagation delay time is removed, to derive the coefficients of the interpolation function and the extrapolation function; and

a final band extension module outputting the final band-extended S-parameter when the difference between the real part of the band-extended S-parameter and the real part of the band-limited S-parameter from which the propagation delay time is removed is not greater than a predetermined reference value.

Preferably, the pre-processing unit may include:

a remove module removing the propagation delay time of a predetermined maximum period from the S-parameter in which the measurement band is limited, and deriving the imaginary part of the S-parameter from which the propagation delay time is removed,

a band extension error derivation module deriving a band extension error by calculating an NMSE (Normalized Mean Square Error) with the difference between the real part of the band-extended S-parameter of the coefficient derivation module and the real part of the band-limited S-parameter from which the propagation delay time is removed; and

a propagation delay time update module reducing the maximum period of the propagation delay time to a given period and transmitting the propagation delay time of the reduced period to the removal module, when the calculated band extension error is greater than the predetermined reference value.

Preferably, the interpolation function may be provided

to be set as a polynomial in a form of an odd function having only odd terms in the imaginary part of the S-parameter in which the measurement band is limited,

to allow the interpolation function value to be zero at 0 Hz with extended low frequency in order to have a frequency response characteristic in the interpolation function in the polynomial in the form of the odd function having only odd terms, and

to allow the interpolation function value at a frequency where the imaginary number of the interpolation function of the low frequency band meets the imaginary number of the S-parameter from which the delay time is removed and the S-parameter value to be equal to each other, and differential values thereof to be equal to each other.

Preferably, the extrapolation function may be provided

to be set as a polynomial in a form of an odd function having only odd terms in the imaginary part of the S-parameter in which the measurement band is limited,

to allow the extrapolation function value at a frequency where the imaginary number of the extrapolation function of the extended high-frequency band meets the imaginary number of the S-parameter from which the delay time is removed and the S-parameter value to be equal to each other, in order to have a frequency response characteristic in the interpolation function of the polynomial in the form of the odd function having only the odd terms,

to allow differential values of the extrapolation function value at the frequency where the imaginary number of the extrapolation function of the extended high-frequency band meets the imaginary number of the S-parameter from which the delay time is removed and the S-parameter value to be equal to each other, and

to set an end-point frequency of the extended high-frequency band to a predetermined maximum frequency.

According to present invention, a system for analyzing passive network according to an embodiment is configured to extend the frequency band with the interpolation function of the low frequency band and the extrapolation function of the high frequency band for S-parameters with a limited measurement band, adjust the propagation delay time for the band-extended S-parameter to derive the final band-extended S-parameter, and analyze the passive network with respect to the time response on the basis of the measured output voltage waveform and the output voltage waveform estimated by performing convolution on the impulse response to the derived final band-extended S-parameter and the input voltage waveform of the passive network, thereby improving the time response performance of the passive network without a complex circuit conversion process, and making it possible to be capable of lightweight structures.

In addition, as the band extension error is adjusted not greater than the reference value by adjusting the propagation delay time removed from the band-limited S-parameter of the instrument, it is possible to improve the accuracy of the impulse response of the IFT.

### BRIEF DESCRIPTION OF THE DRAWINGS

The accompanying drawings with respect to the specification illustrate preferred embodiments of the present invention and serve to further convey the technical idea of the present invention together with the description of the present invention given below, and accordingly, the present invention should not be construed as limited only to descriptions in the drawings, in which:

FIG. 1 is a diagram illustrating causal performance according to a conversion error of an S-parameter with limited measurement bandwidth into an impulse response in the related art;

FIG. 2 is a block diagram illustrating a system for analyzing passive network, according to an embodiment of the present invention;

FIG. 3 is a diagram illustrating S-parameters for explaining band extension of the interpolator of FIG. 2;

FIG. 4 is a diagram illustrating a low-frequency interpolator and a high-frequency extrapolation function of the interpolator of FIG. 2, respectively;

FIG. 5 is a detailed configuration diagram illustrating the interpolator of FIG. 2;

FIG. 6 is a detailed configuration diagram illustrating a pre-processing unit of the interpolator of FIG. 5;

FIG. 7 is a detailed configuration diagram illustrating a band extension unit of the interpolator in FIG. 5; and

FIG. 8 illustrates output waveform diagrams of each unit of the interpolator in FIG. 5.

### DETAILED DESCRIPTION OF THE INVENTION

Hereinafter, embodiments of the present invention will be described in detail with reference to the accompanying drawings so that those skilled in the art can easily carry out the present invention. The present invention may, however, be embodied in many different forms and should not be construed as limited to the embodiments set forth herein. In order to clearly illustrate the present invention, parts not related to the description are omitted, and similar parts are denoted by like reference characters throughout the specification.

According to an embodiment, by measuring the output of the passive network with limiting the frequency band using the instrument, and then extending the low and high frequency bands of the band-limited S-parameter obtained from the instrument, the passive network is analyzed based on the output voltage value of the passive network which is estimated by performing convolution on the result obtained by performing IFT on the S-parameter of the band-extended extension function and the input of the passive network.

Hereinafter, a passive network analysis system according to an embodiment of the present invention will be described in detail with reference to the accompanying drawings.

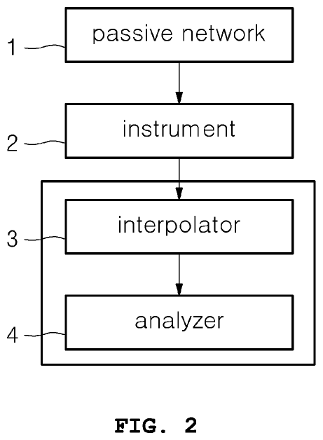

FIG. 2 is a view showing an analysis system of a passive network according to an embodiment. Referring to FIG. 2, the system is configured to measure the output voltage waveform of the passive network for the input voltage waveform supplied from the outside with limiting the frequency band thereof using the instrument, extend the frequency band based on each of the lowest and highest frequencies of the imaginary part of the measured band-limited S-parameter, generate an interpolation function and an extrapolation function of the extended low-frequency band and high-frequency band, respectively, derive the band-extended S-parameter using a sum of the imaginary part of the generated interpolation function and extrapolation function and the imaginary part of the band-limited S-parameter, and analyze the output voltage waveform of the passive network estimated by performing convolution on the impulse response obtained by performing IFT on the derived band-extended S-parameter, and the input voltage waveform of the passive network, thereby analyzing the time response performance of the passive network. Accordingly, the system may include a passive network 1, an instrument 2, an interpolator 3, and an analyzer 4.

The interpolator 3 and the analyzer 4 according to an embodiment may be directly connected through a wire or a connector, etc. as shown in FIG. 2, and both may be configured in such a manner as to be provided in one device.

Here, the passive network 1 is provided with a semiconductor package or a printed circuit board including various components and devices, and the output of the passive network is measured by the instrument 2 with respect to the input supplied from the outside. Here, the output of passive network 1 measured by the instrument 2 is the S-parameter of the frequency domain in which measurement frequency band is limited (hereinafter, referred to as band-limited S-parameter).

The interpolator 3 removes a propagation delay time from the band-limited S-parameter to derive the imaginary part of the band-limited S-parameter; extends the low frequency band based on the lowest frequency and the high frequency band based on the highest frequency of the imaginary part of the derived band-limited S-parameter; and then generates an interpolation function of the extended low-frequency band and an extrapolation function of the extended high-frequency band.

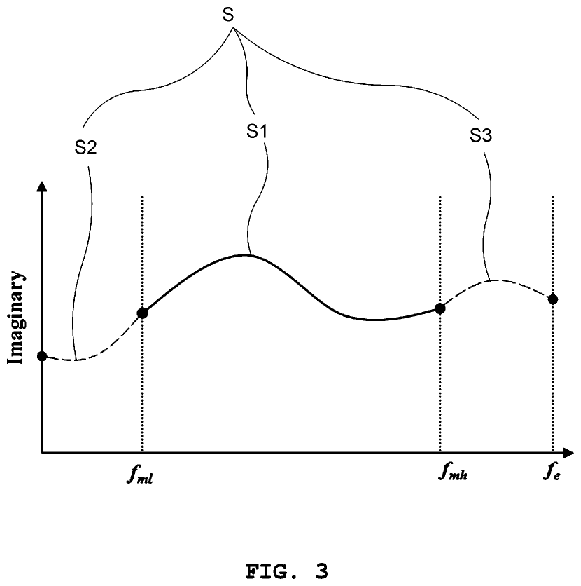

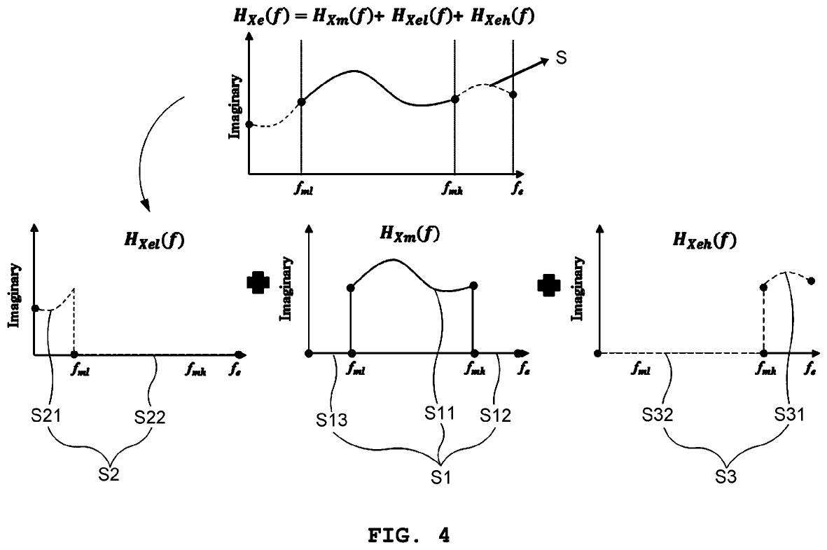

FIG. 3 is a diagram illustrating the concept of extending each of a low frequency band and a high frequency band of the band-limited S-parameter; and FIG. 4 is a diagram illustrating how to generate an interpolation function of the extended low-frequency band and an extrapolation function of the extended high-frequency band. Referring to FIGS. 3 and 4, S2 is an interpolation function of the low frequency band which is extended based on the lowest frequency of the imaginary part S1 of the band-limited S-parameter, and S3 is an extrapolation function of the high-frequency band which is extended based on the highest frequency of the imaginary part S1 of the band-limited S-parameter.

That is, as the band-limited S-parameter is measured in a range from the lowest frequency fₘₗ to the highest frequency fₘₕ, the band-limited lowest frequency fₘₗ is extended to the low frequency band. Therefore, the interpolation function S2 is the imaginary part of the S-parameter from the frequency 0 Hz of the extended low-frequency band to the lowest frequency fₘₗ of the band-limited S-parameter, and the extrapolation function S3 is the imaginary part of the S-parameter ranging from the highest frequency fₘₕ of the band-limited S-parameter to the extended frequency fₑ.

As such, as the interpolator 3 generates the interpolation function S2 and the extrapolation function S3 by inputting the measured band-limited S-parameter, the lowest frequency of the S-parameter signal extends from fₘₗ to zero, and the highest frequency of the S-parameter signal extends from fₘₕ to fₑ.

Herein, the S-parameter H_{Xe}(f) of the band extension function S may be decomposed as shown in FIG. 4. More specifically, with reference to FIG. 4, S-parameter H_{Xe}(f) is decomposed into the S-parameter part H_{Xel}(f) of the interpolation function S2, the band-limited S-parameter part H_{Xm}(f), and the S-parameter part H_{Xeh}(f) of the extrapolation function S3. The S-parameter of the interpolation function S2 is a combination of a first part S21 having an interpolated response in a frequency range of 0 to fₘₗ and a second part S22 having an S-parameter value of 0 in a frequency range of fₘₗ to fₑ.

In addition, the band-limited S-parameter is a combination of a first part S12 having an S-parameter value of 0 in a frequency range of 0 to fₘₗ, a second part S11 having a measured response in a frequency range of fₘₗ to fₘₕ, and a third part S13 having an S-parameter value of 0 in a frequency range of fₘₕ to fₑ.

In addition, the extrapolation function S3 is a combination of a first part S32 having an S-parameter value of 0 in a frequency range of 0 to fₘₕ, and a second part S31 having an extrapolated response in a frequency range of fₘₕ to fₑ.

The interpolator 3 is configured to extend the measurement band by adding the interpolation function of the extended low frequency band and the extrapolation function of the extended high frequency band; restore the real part of the band-extended S-parameter by performing Hilbert transform on the band-extended S-parameter; and derive coefficients of the interpolation function and the extrapolation function using a difference between the real part of the restored S-parameter and the real part of the S-parameter from which the propagation delay time is removed, to derive the final band extended S-parameters.

In addition, the interpolator 3 derives the impulse response by performing IFT on the final band-extended S-parameter.

Meanwhile, since the maximum period of the predetermined propagation delay time is reduced to a given period so that the difference between the real part of the restored S-parameter and the real part of the S-parameter from which the propagation delay time is removed is not greater than the predetermined reference value, the interpolator 3 may address the reduction of impulse response accuracy, occurring due to the band extension error.

The analyzer 4 may analyze the output voltage waveform of the passive network estimated by performing convolution on the impulse response and the input voltage waveform of the passive network, to analyze the time response of the passive network.

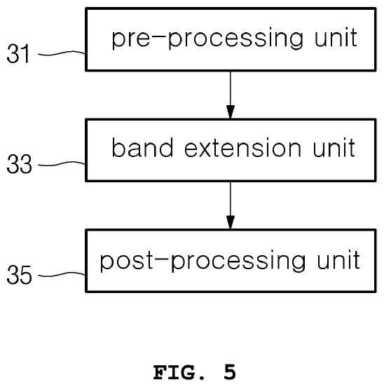

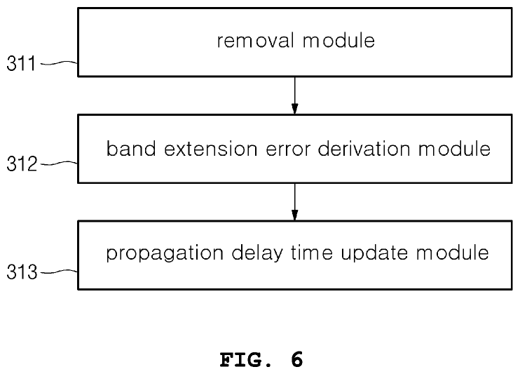

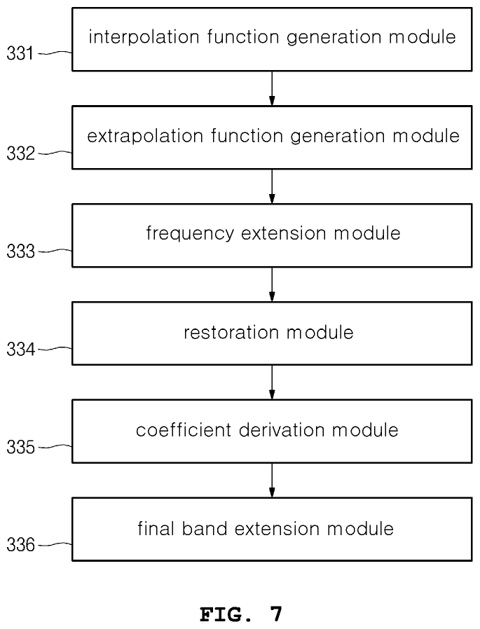

FIG. 5 is a view illustrating a detailed configuration of the interpolator 3 shown in FIG. 2; FIG. 6 is a detailed configuration diagram of the pre-processing unit 31 of FIG. 5; and FIG. 7 is a detailed configuration diagram of the band extension unit 33 of FIG. 5. Referring to FIGS. 5 to 7, the interpolator 2 is configured to derive the final band-extended S-parameter with the interpolation function of the band-extended low-frequency band and the extrapolation function S2 of the band-extended high-frequency band, on the basis of the lowest and highest frequencies of the imaginary part of the S-parameter from which the propagation delay time is removed. Accordingly, the interpolator 3 may be configured to include a pre-processing unit 31, a band extension unit 33, and a post-processing unit 35.

Referring to FIG. 6, the pre-processing unit 31 is configured to remove the propagation delay time of the predetermined maximum period from the band-limited S-parameter and then derive the imaginary part of the band-limited S-parameter. Accordingly, the pre-processing unit 31 may include a removal module 311.

The removal module 311 removes the predetermined propagation delay time τ from the band-limited S-parameter and then derives the imaginary part of the band-limited S-parameter, to deliver the derived band-limited S-parameter to the band extension unit 33. Here, the initial value of the propagation delay time is set as the maximum value of a group delay. Here, the group delay may be derived as a ratio of a phase value <Hₘ(f) of the band-limited S-parameter to 2πf.

In addition, the S-parameter H_{m_zd}(f) from which the propagation delay time is removed is derived from the product of the band-limited S-parameter Hₘ(f) and e^{j2πfτ}, and the S-parameter H_{m_zd}(f) from which the propagation delay time τ is removed includes a real part H_{Rm_zd}(f) and an imaginary part H_{Xm_zd}(f).

In addition, the pre-processing unit 31 may include a band extension error derivation module 312 and a propagation delay time update module 313, which reduce the maximum period of the propagation delay time to a predetermined period, and deliver the reduced propagation delay time of a predetermined period to the removal module 311, when the band extension error, which is calculated by the difference between the real part of the band-extended S-parameter and the real part of the band-limited S-parameter from which the propagation delay time is removed, is greater than the reference value.

Here, the maximum period, the predetermined period, and the reference value may be values which have been already applied to the passive network. Although each maximum period, predetermined period, and reference values are not specifically specified here, those skilled in the art should understand these.

Meanwhile, the band extension unit 33 is configured to extend the limited frequency band by adding the interpolation function of the low frequency band and the extrapolation function of the high frequency band to the imaginary part of the derived band-limited S-parameter, restore the real part of the band-extended S-parameter by performing Hilbert transform on the imaginary part of the band-extended S-parameter, derive the coefficients of the interpolation function and the extrapolation function using the difference between the real part of the restored S-parameter and the real part of the S-parameter from which the propagation delay time is removed, to output the band-extended S-parameters of the derived coefficients as the final band-extended S-parameters. Referring to FIG. 7, the band extension unit 33 includes an interpolation function generation module 331, an extrapolation function generation module 332, a frequency extension module 333, a restoration module 334, a coefficient derivation module 335, and a final band extension module 336.

The interpolation function generation module 331 generates the interpolation function S2 extended to the low frequency band based on the lowest frequency fₘₗ of the imaginary part H_{Xm_zd}(f) of the S-parameter from which the propagation delay time is removed, in which the interpolation function S2 is set as a polynomial f^{2k-1} in the form of an odd function including only odd terms in the imaginary part of the S-parameter with limited measurement band. Where, k is a natural number.

Here, the interpolation function S2 is set such that the value of the interpolation function is zero at 0 Hz with extended low frequency band, and the value of the interpolation function at the lowest frequency fₘₗ where the imaginary part of the interpolation function of the low frequency band meets the imaginary part of the S-parameter from which the delay time is removed, and the value of the S-parameter from which the propagation delay time is removed, are equal to each other, and differential values thereof are equal to each other as well, in order to have the frequency response characteristic of the interpolation function S2 of the polynomial in the form of the odd function including only odd terms.

Meanwhile, the extrapolation function generation module 332 may set the extrapolation function S3 as a polynomial f^{2j-1} in a form of an odd function having only odd terms in the imaginary part of the S-parameter with limited measurement band. Where, j is a natural number.

Here, the extrapolation function S3 is set such that the extrapolation function value at the frequency fₘₕ, where the imaginary number of the extrapolation function S3 of the extended high-frequency band meets the imaginary number of the S-parameter from which the delay time is removed, and the S-parameter value from which the propagation delay time is removed, are equal to each other, and differential values of the extrapolation function value and the S-parameter value are equal to each other, in order to have the frequency response characteristic of the extrapolation function of the polynomial of the odd function including only odd terms.

The interpolation function S2 of the low frequency band and the extrapolation function S3 of the high frequency band are transmitted to the frequency expansion module 333, and the frequency expansion module 333 combines the interpolation function S2 of the extended low frequency band, the extrapolation function S3 of the extended high frequency band, and the imaginary part of the band-limited S-parameter, to output the imaginary part of the band-extended S-parameter.

Then, the imaginary part of the band-extended S-parameter is transmitted to the restoration module 334.

The restoration module 334 restores the real part H_{Re}(f) of the band-extended S-parameter by performing Hilbert transform H_{T}{ } on the imaginary part H_{Xe}(f) of the band-extended S-parameter, and delivers the real part H_{Re}(f) of the band-extended S-parameter to the coefficient derivation module 335.

More specifically, the real part H_{Re}(f) of the band-extended S-parameter(S) may be derived by performing Hilbert transform H_{T}{ } on a sum of the imaginary part H_{Xel}(f) of the interpolation function S2 of the extended low-frequency band, the imaginary part H_{Xeh}(f) of the extrapolation function S3 of the extended high-frequency band, and the imaginary part H_{Xm}(f) of the band-limited S-parameter S1, that is, H_{Xm}(f)+H_{Xel}(f) +H_{Xeh}(f)

The coefficient derivation module 335 derives a coefficient aₖ of the interpolation function S2 and a coefficient bⱼ of the extrapolation function S3 based on the real part H_{Re}(f) of the band-extend S-parameter S, in which the coefficients aₖ and bⱼ may be derived by LSE (least square error) technique that minimizes a difference between the real part H_{Re}(f) of the band-extended S-parameter and the real part H_{Rm}(f) of the band-limited S-parameter from which the propagation delay time τ is removed.

Herein, the real part H_{Re}(f) of the band-extended S-parameter and the real part H_{Rm}(f) of the band-limited S-parameter from which the propagation delay time τ is removed may be expressed by the following Equation 1, in which each term of Equation 1 may satisfy Equation 2 below.

$${H}_{RM} ( {f}_{i} ) = HT \{ {H}_{Xm} ( f ) + {H}_{Xel} ( f ) + {H}_{Xeh} ( f ) , {f}_{i} \} , ( {f}_{ml} \leq {f}_{i} \leq {f}_{mh} ) \qquad [ Equation 1 ]$$

$$HT \{ {H}_{Xel} ( f ) , {f}_{i} \} + HT \{ {H}_{Xeh} ( f ) , {f}_{i} \} = {H}_{Rm} ( {f}_{i} ) - HT \{ {H}_{Xm} ( f ) , {f}_{i} \}$$

$${\sum }_{k = 3}^{K} {a}_{k} \cdot {F}_{lk} ( {f}_{i} ) + {\sum }_{j = 3}^{J} {b}_{j} \cdot {F}_{hj} ( {f}_{i} ) = C ( {f}_{i} ) \qquad [ Equation 2 ]$$

$${F}_{lk} ( {f}_{i} ) = HT \{ {f}^{2 k - 1} - ( k - 1 ) \cdot {f}_{ml}^{2 ( k - 2 )} \cdot {f}^{3} + ( k - 2 ) \cdot {f}_{ml}^{2 ( k - 1 )} \cdot f , {f}_{i} \}$$

$${F}_{hj} ( {f}_{i} ) = HT \{ {( f - {f}_{e} )}^{2 j - 1} - ( j - 1 ) \cdot {f}_{b}^{2 ( j - 2 )} \cdot {( f - {f}_{e} )}^{3} + ( j - 2 ) \cdot {f}_{b}^{2 ( j - 1 )} \cdot ( f - {f}_{e} ) , {f}_{i} \}$$

$$C ( {f}_{i} ) = {H}_{Rm} ( {f}_{i} ) - HT \{ {H}_{Xm} ( f ) , {f}_{i} \} - HT \{ ( \frac{{q}_{l}}{2 {f}_{ml}^{2}} - \frac{{p}_{l}}{2 {f}_{ml}^{3}} ) {f}^{3} - ( \frac{{q}_{l}}{2} - \frac{3 {p}_{l}}{2 {f}_{ml}} ) f + ( \frac{{q}_{h}}{2 {f}_{b}^{2}} + \frac{{p}_{h}}{2 {f}_{b}^{3}} ) {( f - {f}_{e} )}^{3} - ( \frac{{q}_{h}}{2} + \frac{3 {p}_{h}}{2 {f}_{b}} ) ( f - {f}_{e} ) , {f}_{i} \}$$

Where, k is a natural number from 3 to K, j is a natural number from 3 to J, Fₗₖ(fᵢ) is a function associated with Hilbert transform of the low frequency band-extended interpolation function at frequency fᵢ, Fₕⱼ(fᵢ) is a function associated with Hilbert transform of the high frequency band-extended extrapolation function at frequency fᵢ, and C(fᵢ) is a constant part. Herein, the coefficient aₖ of the low frequency band-extended interpolation function H_{Xel}(f) and the coefficient bⱼ of the high frequency band-extended extrapolation function H_{Xeh}(f) may be simultaneously derived. In addition, pₗ is the interpolation function value at the lowest frequency fₘₗ, qₗ is a differential value of the interpolation function at the lowest frequency fₘₗ, pₕ is the extrapolation function value at the highest frequency fₘₕ, qₕ is a differential value of the extrapolation function at the highest frequency fₘₕ. Herein, the interpolation function value at the lowest frequency fₘₗ where the imaginary part of the interpolation function at the low frequency band meets the imaginary part of the S-parameter from which the delay time is limited, and the S-parameter value from which propagation delay time is removed are both equal to pₗ, and differential values thereof are both equal to

In addition, the extrapolation function value at the highest frequency fₘₕ where the imaginary part of the extrapolation function of the high-frequency band meets the imaginary part of the S-parameter from which the delay time is removed, and the S-parameter value from which propagation delay time is removed are both equal to pₕ, and differential values thereof are both equal to qₕ. Here, f_{b}=fₑ−fₘₕ in equation above.

To apply the LSE (Least Square Error) technique that minimizes the difference between the real part H_{Re}(f) of the band-extended S-parameter and the real part H_{Rm}(f) of the band-limited S-parameter from which the propagation delay time τ is removed, the interpolation function and the extrapolation function may be expressed as a matrix of the [X][A]=[Y] structure for each frequency index. The matrix structure of the interpolation function and the extrapolation function for each frequency index may be expressed by Equation 3.

$$[ X ] = [ \begin{matrix}\begin{matrix}\begin{matrix}{F}_{l 3} ( {f}_{1} ) {F}_{l 4} ( {f}_{1} ) … {F}_{lK} ( {f}_{1} ) {F}_{h 3} ( {f}_{1} ) {F}_{h 4} ( {f}_{1} ) … {F}_{hJ} ( {f}_{1} ) \\ {F}_{l 3} ( {f}_{2} ) {F}_{l 4} ( {f}_{2} ) … {F}_{lK} ( {f}_{2} ) {F}_{h 3} ( {f}_{2} ) {F}_{h 4} ( {f}_{2} ) … {F}_{hJ} ( {f}_{2} )\end{matrix} \\ ⋮\end{matrix} \\ {F}_{l 3} ( {f}_{V} ) {F}_{l 4} ( {f}_{V} ) … {F}_{lK} ( {f}_{V} ) {F}_{h 3} ( {f}_{V} ) {F}_{h 4} ( {f}_{V} ) … {F}_{hJ} ( {f}_{V} )\end{matrix} ] \qquad [ Equation 3 ]$$

$$[ A ] = [ \begin{matrix}\begin{matrix}\begin{matrix}{a}_{3} & {a}_{4} … {a}_{K}\end{matrix} & {b}_{3}\end{matrix} & {{b}_{4} … {b}_{J} ]}^{T}\end{matrix}$$

$$[ Y ] = {[ \begin{matrix}C ( {f}_{1} ) & C ( {f}_{2} ) …\end{matrix} C ( {f}_{V} ) ]}^{T}$$

Since the product of a set [A] of coefficients aₖ and bⱼ, and a set [X] of frequency polynomials to which the coefficients are applied is a set [Y] of constant terms and frequency polynomials to which the coefficients are not applied, the set [A] of coefficients aₖ may be derived by applying the LSE (least square error) technique, and a set [A] of coefficients aₖ may be expressed by Equation 4 below.

[Equation 4]

[Â]=([X]^{H}[X])⁻¹[X]^{H}[Y]

Accordingly, the imaginary part H_{Xel}(f) of the interpolation function having the coefficient aₖ derived through the LSE technique may be expressed by Equation 5 below.

$${H}_{Xel} ( f ) = \{ \begin{matrix}\begin{matrix}\begin{matrix}{\sum }_{k = 3}^{K} {a}_{k} \cdot \{ {f}^{2 k - 1} - ( k - 1 ) \cdot {f}_{ml}^{2 ( k - 2 )} \cdot \\ {f}^{3} + ( k - 2 ) \cdot {f}_{ml}^{2 ( k - 1 )} \cdot f \} +\end{matrix} \\ ( \frac{{q}_{l}}{2 {f}_{ml}^{2}} - \frac{{p}_{l}}{2 {f}_{ml}^{3}} ) {f}^{3} - ( \frac{{q}_{l}}{2} - \frac{3 {p}_{l}}{2 {f}_{ml}} ) f ,\end{matrix} & ( 0 \leq f \leq {f}_{ml} ) \\ 0 , & , else\end{matrix} \qquad [ Equation 5 ]$$

Meanwhile, the coefficient bⱼ of the extrapolation function (S3 in FIG. 3) of the extended high-frequency band may be derived from Equations 1 to 5 described above, and the process of deriving the coefficient bⱼ of the extrapolation function should be interpreted as described above unless even though not specifically specified here, and should not limit the present invention.

Herein, the difference between the real part H_{Re}(f) of the band-extended S-parameter and the real part H_{Rm}(f) of the band-limited S-parameter from which the propagation delay time is removed is delivered to the band extension error derivation module 312 of the pre-processing unit 31.

The band extension error derivation module 312 defines, as a band extension error, the difference between the real part H_{Re}(f) of the band-extended S-parameter and the real part H_{Rm}(f) of the band-limited S-parameter from which the propagation delay time is removed. Here, the band extension error is derived from the NMSE (Normalized Mean Square Error) for the real part H_{Re}(f) of the band-extended S-parameter and the real part H_{Rm}(f) of the band-limited S-parameter from which the propagation delay time is removed.

Herein, the propagation delay time update module 313 reduces the previously applied propagation delay time to a predetermined period (preferably 100 psec), when the derived band extension error is greater than the predetermined reference value NMSEₜₕ, and the reduced predetermined period is transmitted to the removal module 311.

As described above, the removal module 311 removes the propagation delay time of a predetermined period from the band-limited S-parameter, derive the imaginary part of the band-limited S-parameter, and then delivers the derived band-limited S-parameter to the band extension unit 33.

Such adjustment of the propagation delay time is repeatedly performed until the derived band extension error is not greater than the predetermined reference value NMSEₜₕ. Here, the derived band-extended S-parameter is delivered to the final band extension module 336, and then delivered to the post-processing unit 35 as a final band-extended S-parameter.

Subsequently, the post-processing unit 35 derives an impulse response by performing IFT on the band-extended S-parameter, and the derived impulse response is transmitted to the analyzer 4. Here, the propagation delay time finally applied to the extracted impulse response can be applied.

Subsequently, the analyzer 4 analyzes the output voltage waveform of the passive network estimated by performing convolution on the impulse response and the input voltage waveform of the passive network, to analyze the time response of the passive network.

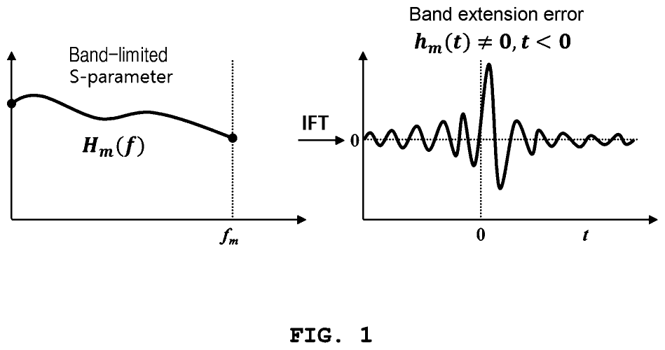

As described with reference to FIGS. 1 to 7, the system for analyzing the passive network according to an embodiment is configured to extend the frequency band with the interpolation function of the low frequency band and the extrapolation function of the high frequency band for S-parameters with limited measurement band, adjust the propagation delay time for the band-extended S-parameter to derive the final band-extended S-parameter, and analyze the time response of the passive network on the basis of the output voltage waveform estimated by performing convolution on the impulse response to the derived final band-extended S-parameter and the input voltage waveform of the passive network, thereby improving the time response performance of the passive network without a complex circuit conversion process, and making it possible to be capable of lightweight structures

In addition, as the band extension error is adjusted not greater than the reference value by adjusting the propagation delay time removed from the band-limited S-parameter of the instrument, it is possible to improve the accuracy of the impulse response of the IFT.

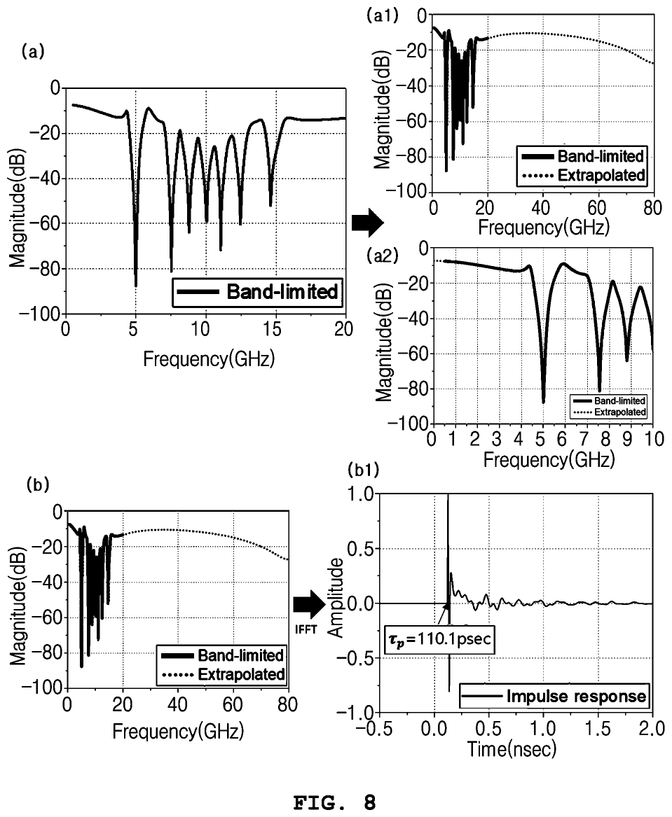

FIG. 8 illustrates output waveform diagrams of each unit according to an embodiment. Referring to FIG. 8, when measuring the S-parameter in a network structure having a frequency range of 0 to 20 GHz as shown in (a) of FIG. 8, it may be confirmed that the S-parameter measured in the network is extended as S-parameter signal of the extension function as shown in (b) of FIG. 8, by extending the low frequency band as shown in (a1) of FIG. 8 and high frequency band as shown in (a2) of FIG. 8, and causality error does not occur in the impulse response derived by performing IFT on the S-parameter of the extension function as shown in (b1) of FIG. 8.

Although the embodiments of the present invention have been described in detail above, the scope of the present invention is not limited thereto, but various modifications and improvements by those skilled in the art using the basic concept of the present invention as defined in the following claims also fall within the scope of the present invention.

[Description of Reference Numerals]

1: passive network

2: instrument

3: interpolator

31: pre-processing unit

311: removal module

312: band extension error derivation module

313: propagation delay time update module

33: band extension unit

331: interpolation function generation module

332: extrapolation function generation module

333: frequency extension module

334: restoration module

335: coefficient derivation module

336: final band extension module

35: post-processing unit

4: analyzer

What is claimed is:

1. A system for analyzing passive network, configured to analyze time response of a passive network with a band-limited S-parameter of an instrument, the system comprising:
an interpolator removing a propagation delay time from the band limited S-parameter of the instrument, deriving an imaginary part of the S-parameter from which the propagation delay time is removed, adding an interpolation function of a low frequency band and an extrapolation function of a high frequency band to the derived imaginary part to derive an imaginary part of a band-extended S-parameter, deriving an impulse response by performing IFT after restoring a real part of the band-extended S-parameter by performing Hilbert transform on the imaginary part of the derived band-extended S-parameter; and
an analysis device analyzing time response of the passive network by analyzing an output voltage waveform of the passive network estimated by performing convolution on the impulse response and an input voltage waveform of the passive network,
wherein the interpolator is configured to adjust the propagation delay time according to a comparison result of a difference between the real part of the band-extended S-parameter and a real part of the band-limited S-parameter with a predetermined reference value.

2. The system of claim 1, wherein the interpolator comprises:
a pre-processing unit that removes the propagation delay time from the band-limited S-parameter and then derives the imaginary part of the band-limited S-parameter from the band-limited S-parameter;
a band extension unit extending the frequency band by adding the interpolation function of the low frequency band and the extrapolation function of the high frequency band to the imaginary part of the derived band-limited S-parameter, restoring the real part of the band-extended S-parameter by performing Hilbert transform on the imaginary part of the band-extended S-parameter, and deriving coefficients of the interpolation function and the extrapolation function by using the difference between the real part of the restored S-parameter and the real part of the S-parameter from which the propagation delay time is removed, to output a final band-extended S-parameter; and
a post-processing unit outputting an impulse response by performing IFT on the derived band-extended S-parameter.

3. The system of claim 2, wherein the band extension unit comprises:
an interpolation function generation module generating the interpolation function of the low frequency band in the imaginary part of the derived band-limited S-parameter;
an extrapolation function generating module generating the extrapolation function of the high frequency band in the imaginary part of the derived band-limited S-parameter;
a frequency extension module extending the measurement band to derive the imaginary part of the band-extended S-parameter by adding the interpolation function of the low frequency band and the extrapolation function of the high frequency band to the imaginary part of the band-limited S-parameter;
a restoration module restoring the real part of the band-extended S-parameter by performing Hilbert transform on the imaginary part of the band-extended S-parameter;
a coefficient derivation module applying an LSE (least square error) technique that minimizes the difference between the real part of the band-extended S-parameter and the real part of the band-limited S-parameter from which the propagation delay time is removed, to derive the coefficients of the interpolation function and the extrapolation function; and
a final band extension module outputting the final band-extended S-parameter when the difference between the real part of the band-extended S-parameter and the real part of the band-limited S-parameter from which the propagation delay time is removed is not greater than a predetermined reference value.

4. The system of claim 3, wherein the pre-processing unit comprises:
a remove module removing the propagation delay time of a predetermined maximum period from the S-parameter in which the measurement band is limited, and deriving the imaginary part of the S-parameter from which the propagation delay time is removed,
a band extension error derivation module deriving a band extension error by calculating an NMSE (Normalized Mean Square Error) with the difference between the real part of the band-extended S-parameter of the coefficient derivation module and the real part of the band-limited S-parameter from which the propagation delay time is removed; and
a propagation delay time update module reducing the maximum period of the propagation delay time to a given period and transmitting the propagation delay time of the reduced period to the removal module, when the calculated band extension error is greater than the predetermined reference value.

5. The system of claim 1, wherein the interpolation function is provided
to be set as a polynomial in a form of an odd function having only odd terms in the imaginary part of the S-parameter in which the measurement band is limited,
to allow the interpolation function value to be zero at 0 Hz with extended low frequency in order to have a frequency response characteristic in the interpolation function in the polynomial in the form of the odd function having only odd terms, and
to allow the interpolation function value at a frequency where the imaginary number of the interpolation function of the low frequency band meets the imaginary number of the S-parameter from which the delay time is removed and the S-parameter value to be equal to each other, and differential values thereof to be equal to each other.

6. The system of claim 5, wherein the extrapolation function is provided
to be set as a polynomial in a form of an odd function having only odd terms in the imaginary part of the S-parameter in which the measurement band is limited,
to allow the extrapolation function value at a frequency where the imaginary number of the extrapolation function of the extended high-frequency band meets the imaginary number of the S-parameter from which the delay time is removed and the S-parameter value to be equal to each other, in order to have a frequency response characteristic in the interpolation function of the polynomial in the form of the odd function having only the odd terms,
to allow differential values of the extrapolation function value at the frequency where the imaginary number of the extrapolation function of the extended high-frequency band meets the imaginary number of the S-parameter from which the delay time is removed and the S-parameter value to be equal to each other, and
to set an end-point frequency of the extended high-frequency band to a predetermined maximum frequency.
